(19) United States
(12) Patent Application Publication
(10) Pub. No.: US 2025/0335354 A1
(43) Pub. Date: Oct. 30, 2025

(54) METHOD FOR ESTABLISHING MEMORY CELL GROUP INCLUDING DIFFERENT MEMORY CELLS

(71) Applicant: Winbond Electronics Corp., Taichung City (TW)

(72) Inventors: Kuo-Min Liao, Taichung City (TW); Tien-Yu Liao, Taichung City (TW); Chien-Han Liao, Kaohsiung City (TW)

(73) Assignee: Winbond Electronics Corp., Taichung City (TW)

(21) Appl. No.: 18/677,916

(22) Filed: May 30, 2024

(30) Foreign Application Priority Data
Apr. 25, 2024 (TW) 113115553

(51) Int. Cl. G06F 12/06

(52) U.S. Cl. CPC G06F 12/0653

(57) ABSTRACT

A method for establishing a memory cell group including different memory cells includes following steps. A memory cell array including memory cells and a layout pattern of the memory cell array are provided. A pattern recognition apparatus for performing a recognition step on the layout pattern is provided. The recognition step includes: dividing the memory cells in an n^{th} row of rows in the memory cell array into row groups, where the row groups are identical, and the memory cells in the row group are different; determining whether preceding n rows and succeeding n rows of the rows are repeated. According to a recognition result provided by the pattern recognition apparatus through performing the recognition step, a portion of the memory cells is collectively established as a memory cell repeating group, so that the memory cell array is composed of a plurality of the memory cell repeating groups.

### CROSS-REFERENCE TO RELATED APPLICATION

This application claims the priority benefit of Taiwan patent application serial no. 113115553, filed on Apr. 25, 2024. The entirety of the above-mentioned patent application is hereby incorporated by reference herein and made a part of this specification.

### BACKGROUND

### Technical Field

The disclosure relates to a method for establishing a memory cell group including different memory cells.

### Description of Related Art

In the early stages of memory device development, memory cells of different types in the memory device are typically classified for subsequent analysis of product yield and failure modes. Currently, the memory cell types are generally defined manually based on layer stacking structures of the memory cells. Subsequently, enumeration and classification are performed to define groups including the memory cells of different types.

However, manual classification of the memory cell groups often consumes a considerable amount of time and is prone to high error rates, which may consequently lead to ineffective and inaccurate analyses of product yield and failure modes.

### SUMMARY

The disclosure provides a method for establishing a memory cell group including different memory cells. In the method, a layout pattern of the memory cell array is recognized by a pattern recognition apparatus, so as to rapidly and accurately classify the memory cells and define groups composed of the memory cells of different types.

According to an embodiment of the disclosure, a method for establishing a memory cell group including different memory cells is provided, and the method includes following steps. A memory cell array including a plurality of memory cells and a layout pattern of the memory cell array is provided. A pattern recognition apparatus for performing a recognition step on the layout pattern is provided, where the recognition step includes the following. The memory cells in an n^{th} row of rows in the memory cell array are divided into a plurality of row groups, the row groups are identical, and the memory cells in the row groups are different. Whether preceding n rows and succeeding n rows of the rows are repeated is determined. According to a recognition result provided by the pattern recognition apparatus through performing the recognition step, a portion of the memory cells is collectively established as a memory cell repeating group, so that the memory cell array is composed of a plurality of the memory cell repeating groups.

According to an embodiment of the disclosure, a method for establishing a memory cell group including different memory cells is provided, and the method includes following steps. A memory cell array including a plurality of memory cells and a plurality of dummy memory cells and a layout pattern of the memory cell array is provided, where a first row of rows in the memory cell array includes the dummy memory cells. A pattern recognition apparatus for performing a recognition step on the layout pattern is provided, wherein the recognition step includes the following. The memory cells in an n^{th} row of the rows in the memory cell array are divided into a plurality of row groups, the row groups are identical, and the memory cells in the row groups are different. Whether in the row groups in the n^{th} row there are memory cells which are identical to the memory cells in the row group in the first row is determined, where n is a positive integer greater than 1. According to a recognition result provided by the pattern recognition apparatus through performing the recognition step, a portion of the memory cells is collectively established as a memory cell repeating group, so that the memory cell array is composed of a plurality of the memory cell repeating groups.

In view of the above, in the method of establishing the memory cell group including different memory cells according to one or more embodiments of the disclosure, the layout pattern of the memory cell array is recognized and classified by the pattern recognition apparatus. Therefore, the memory cell repeating groups may be rapidly and accurately established, which is conducive to subsequent analyses of product yield and failure modes.

### BRIEF DESCRIPTION OF THE DRAWING

FIG. 1 is a flowchart of a method for establishing a memory cell group according to a first embodiment of the disclosure.

FIG. 2A to FIG. 2F are schematic views of the method for establishing the memory cell group according to the first embodiment of the disclosure.

FIG. 3 is a flowchart of a method for establishing a memory cell group according to a second embodiment of the disclosure.

FIG. 4A to FIG. 4G are schematic views of the method for establishing the memory cell group according to the second embodiment of the disclosure.

### DESCRIPTION OF THE EMBODIMENTS

In a method of establishing a memory cell group according to one or more embodiments of the disclosure, a layout pattern of a memory cell array is recognized by a pattern recognition apparatus, so as to rapidly and accurately classify memory cells and define groups composed of the memory cells of different types, which is conducive to subsequent analyses of product yield and failure modes.

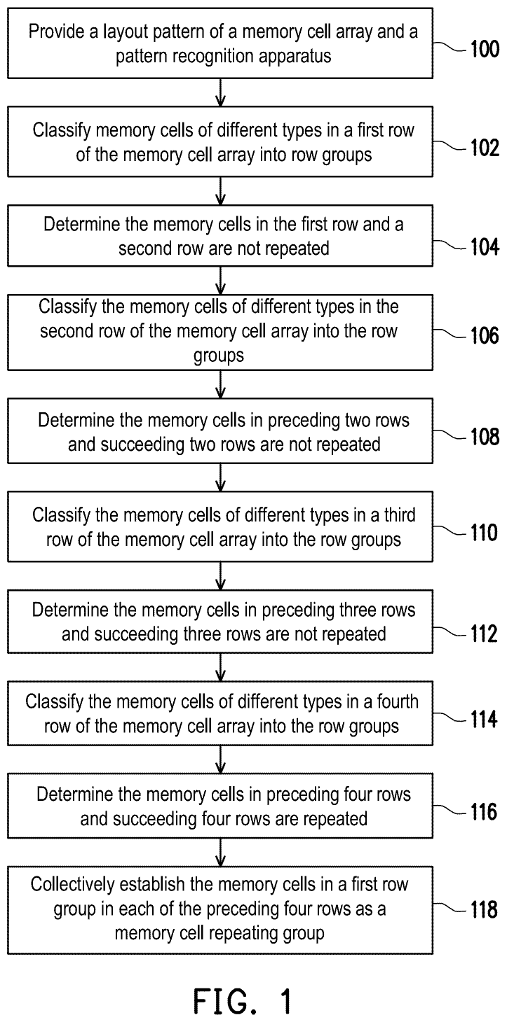

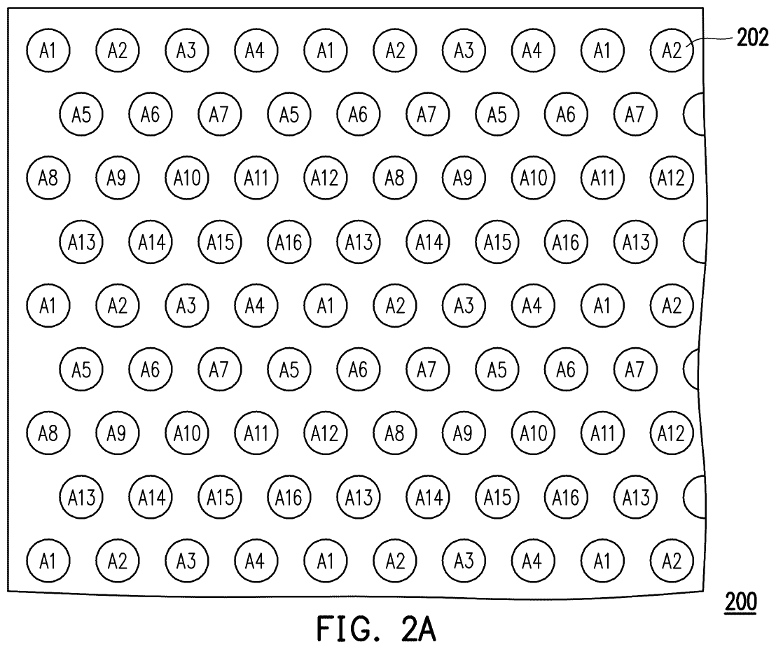

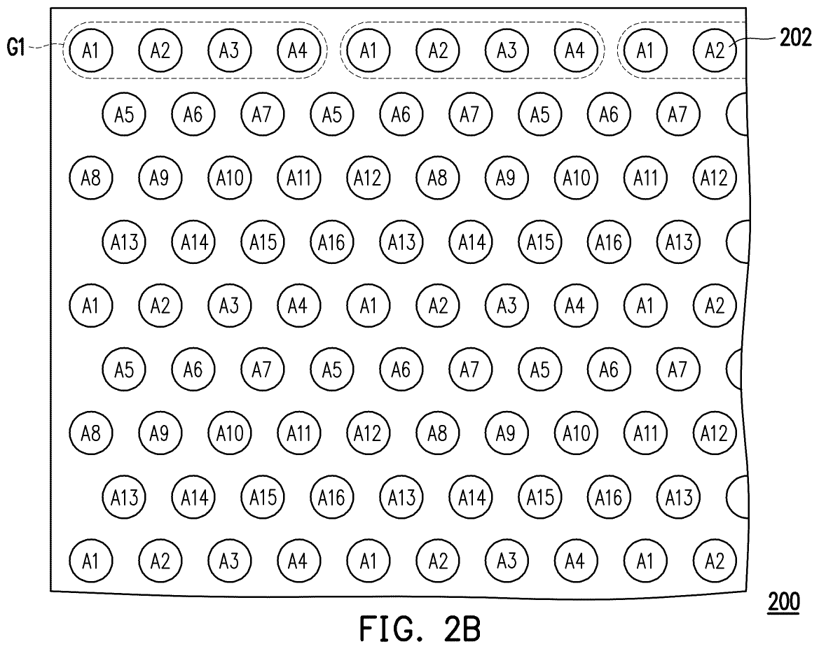

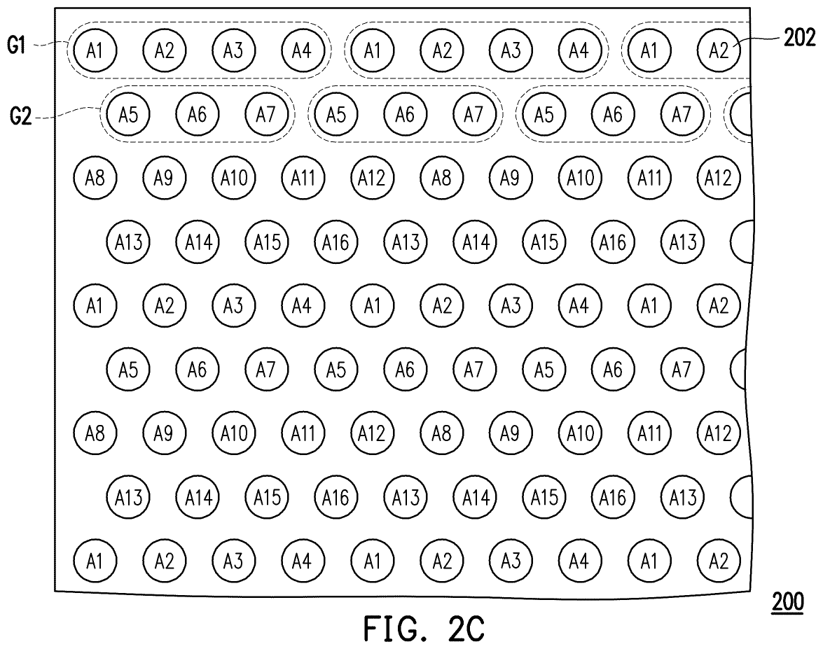

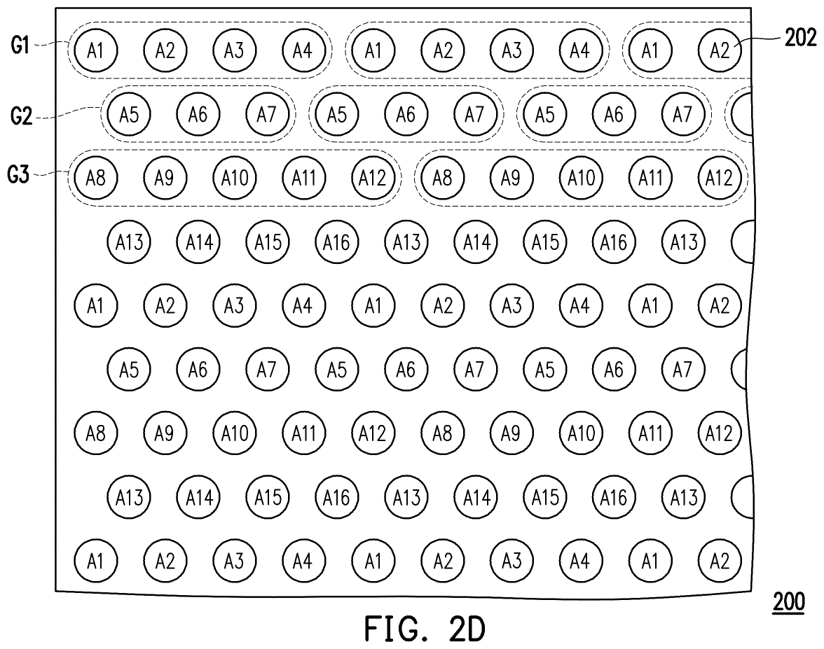

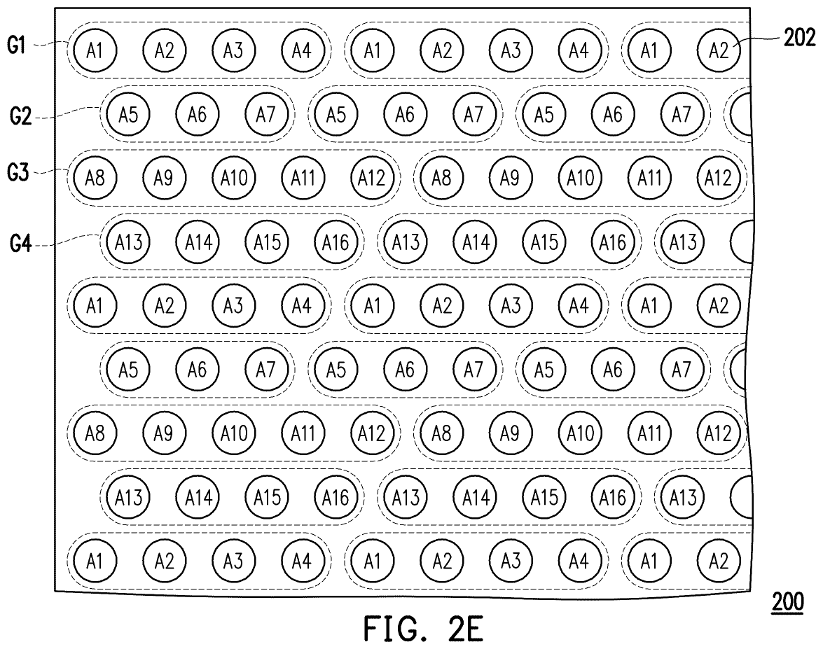

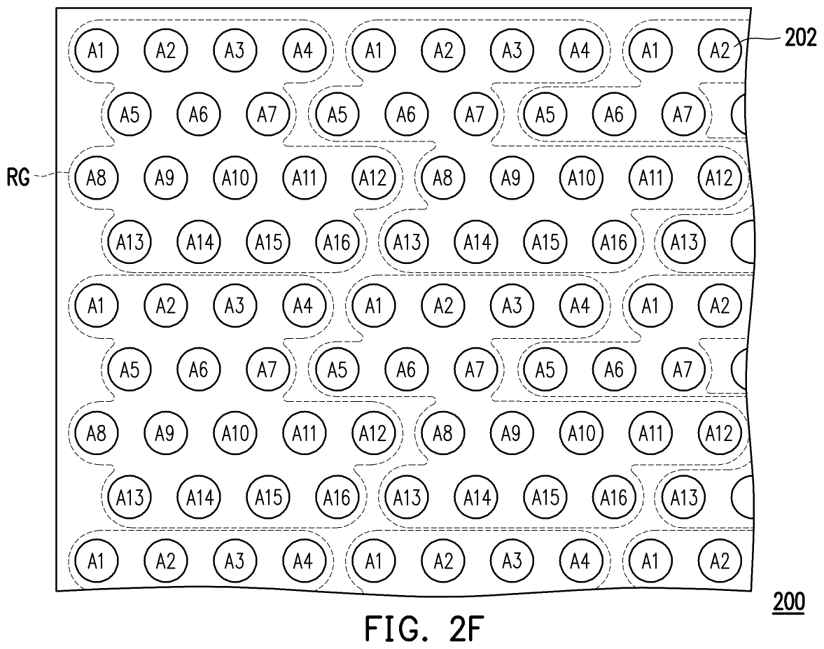

With reference to FIG. 1 and FIG. 2A, in step 100, a memory cell array 200 including a plurality of memory cells 202 is provided. According to this embodiment, in the memory cell array 200, the memory cells 202 in two adjacent columns are alternately arranged, and the memory cells 202 in two adjacent rows are alternately arranged, which should however not be construed as a limitation in the disclosure. The memory cell array 200 includes the memory cells 202 of different types, the memory cells 202 of different types are set repeatedly according to a specific form or standard, and a memory cell group that does not include the memory cells 202 of the same type may be established.

As shown in FIG. 2A, in the memory cell array 200, according to the types of the memory cells 202, the memory cells 202 may be respectively marked as A1, A2, A3, . . . , and A16. In addition, the memory cell array 200 is composed of a plurality of identical memory cell groups; that is, the memory cell array 200 is composed of repeated memory cell groups. Therefore, in this embodiment, the memory cell groups may be referred to as memory cell repeating groups.

In this embodiment, “the memory cells of different types” mean that layer stacking structures of the memory cells are different. Specifically, the memory cells are composed of various layer stacking structures, and depending on the manufacturing steps, different memory cells may have different layer stacking structures. Therefore, the memory cell array 200 includes the memory cells 202 of different types, which should however not be construed as a limitation in the disclosure. In other embodiments, the expression “the memory cells are different” may mean that the memory cells are different in features other than the layer stacking structures.

Therefore, this embodiment aims to classify the memory cells with different layer stacking structures into one memory cell repeating group through pattern recognition, so that the memory cell array 200 may be defined as being composed of the memory cell repeating groups.

In addition, a pattern recognition apparatus that may perform a recognition step on the layout pattern of the memory cell array 200 is provided. In this embodiment, the pattern recognition apparatus may recognize the layout pattern that can present information of the layer stacking structures of the memory cells 202.

In this embodiment, the pattern recognition apparatus may perform the following recognition step:
(1) dividing the memory cells in an n^{th} row of rows in the memory cell array into a plurality of row groups, where the row groups are identical, and the memory cells in the row groups are different;
(2) determining whether preceding n rows and succeeding n rows of the rows are repeated.

In this embodiment, the expression “the preceding n rows and the succeeding n rows are repeated” means that the memory cells in the preceding n rows and the memory cells in the succeeding n rows are repeated. In other words, the group composed of the memory cells in the preceding n rows is the same as the group composed of the memory cells in the succeeding n rows.

Next, with reference to FIG. 1 and FIG. 2B, the layout pattern of the memory cell array 200 is recognized by the pattern recognition apparatus. In step 102, the memory cells 202 in the first row of the memory cell array 200 are recognized, and the memory cells 202 in the first row are divided into a plurality of row groups G1.

In this step, according to the types of the memory cells 202 in the first row, starting from the first memory cell 202 in the first row, the memory cells 202 of non-repeated types are classified into the row groups G1. In addition, since the memory cells 202 in the memory cell array 200 are set repeatedly according to a specific form or standard, the memory cells 202 in the first row may be divided into a plurality of identical row groups G1. In this embodiment, the memory cells 202 in the first row may be divided into the row groups G1, and the row groups G1 include four different memory cells 202 (respectively marked as A1, A2, A3, and A4), which should however not be construed as a limitation in the disclosure. In other words, in the first row of the memory cell array 200, the memory cells 202 are sequentially arranged and set in a manner marked as A1, A2, A3, and A4.

Next, in step 104, it is determined whether the first row and the second row are repeated. In this embodiment, since the memory cells 202 in the first row are different from the memory cells 202 in the second row, it is determined that the first row and the second row are not repeated.

After that, with reference to FIG. 1 and FIG. 2C, in step 106, the memory cells 202 in the second row of the memory cell array 200 are recognized, and the memory cells 202 in the second row are divided into a plurality of row groups G2. In this embodiment, the memory cells 202 in the second row may be divided into the row groups G2, and the row groups G2 include three different memory cells 202 (respectively marked as A5, A6, and A7), which should however not be construed as a limitation in the disclosure.

Next, in step 108, it is determined whether the preceding two rows (the first and second rows) and the succeeding two rows (the third and fourth rows) are repeated. In this embodiment, since the memory cells 202 in the first and second rows are different from the memory cells 202 in the third and fourth rows, it is determined that the preceding two rows and the succeeding two rows are not repeated.

With reference to FIG. 1 and FIG. 2D, in step 110, the memory cells 202 in the third row of the memory cell array 200 are recognized, and the memory cells 202 in the third row are divided into a plurality of row groups G3. In this embodiment, the memory cells 202 in the third row may be divided into the row groups G3, and the row groups G3 include five different memory cells 202 (respectively marked as A8, A9, A10, A11, and A12), which should however not be construed as a limitation in the disclosure.

Next, in step 112, it is determined whether the preceding three rows (the first, second, and third rows) and the succeeding three rows (the fourth, fifth, and sixth rows) are repeated. In this embodiment, since the memory cells 202 in the first, second, and third rows are different from the memory cells 202 in the fourth, fifth, and sixth rows, it is determined that the preceding three rows and the succeeding three rows are not repeated.

With reference to FIG. 1 and FIG. 2E, in step 114, the memory cells 202 in the fourth row of the memory cell array 200 are recognized, and the memory cells 202 in the fourth row are divided into a plurality of row groups G4. In this embodiment, the memory cells 202 in the fourth row may be divided into the row groups G4, and the row groups G4 include four different memory cells 202 (respectively marked as A13, A14, A15, and A16), which should however not be construed as a limitation in the disclosure.

Next, in step 116, it is determined whether the preceding four rows (the first, second, third, and fourth rows) and the succeeding four rows (the fifth, sixth, seventh, and eighth rows) are repeated. In this embodiment, since the memory cells 202 in the memory cell array 200 are set repeatedly according to a specific form or standard, ensuring that the memory cells 202 in the first, second, third, and fourth rows are the same as the memory cells 202 in the fifth, sixth, seventh, and eighth rows, it is determined that the preceding four rows and the succeeding four rows are repeated.

With reference to FIG. 1 and FIG. 2F, in step 118, after determining that the preceding four rows and the succeeding four rows are repeated, the memory cells 202 in the first row group in each of the preceding four rows are collectively established as a memory cell repeating group. In other words, the memory cells 202 (respectively marked as A1, A2, A3, and A4) in the first row group G1 in the first row, the memory cells 202 (respectively marked as A5, A6, and A7) in the first row group G2 in the second row, the memory cells 202 (respectively marked as A8, A9, A10, A11, and A12) in the first row group G3 in the third row, and the memory cells 202 (respectively marked as A13, A14, A15, and A16) in the first row group G4 in the fourth row, a total of 16 memory cells 202, are collectively established as a memory cell repeating group RG.

In this embodiment, the memory cell repeating group RG includes 16 different memory cells 202, and the memory cells 202 of 16 types cover all types of memory cells in the memory cell array 200. As such, based on the memory cell repeating group RG, the memory cell array 200 may be considered as being composed of a plurality of the memory cell repeating groups RG.

In this embodiment, the preceding four rows and the succeeding four rows are repeated, which should however not be construed as a limitation in the disclosure. In other embodiments, when the preceding n rows and the succeeding n rows are not repeated, the above recognition step is performed on the next row until the preceding n rows and the succeeding n rows are repeated, and the memory cell repeating group is established.

According to the above method, the layout pattern of the memory cell array may be rapidly and accurately recognized and classified by the pattern recognition apparatus, so as to establish the memory cell repeating groups, which is conducive to subsequent analyses of product yield and failure modes.

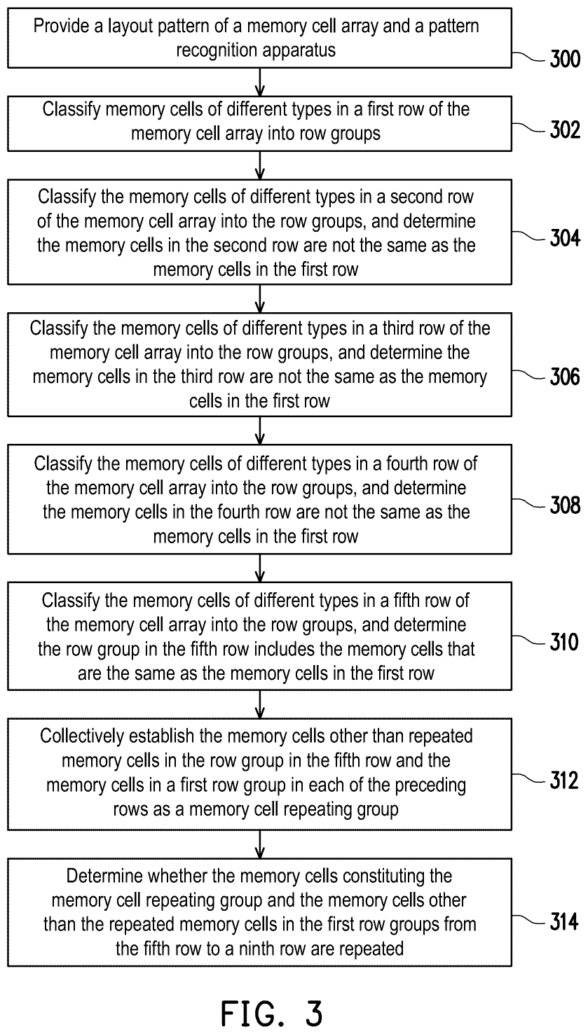

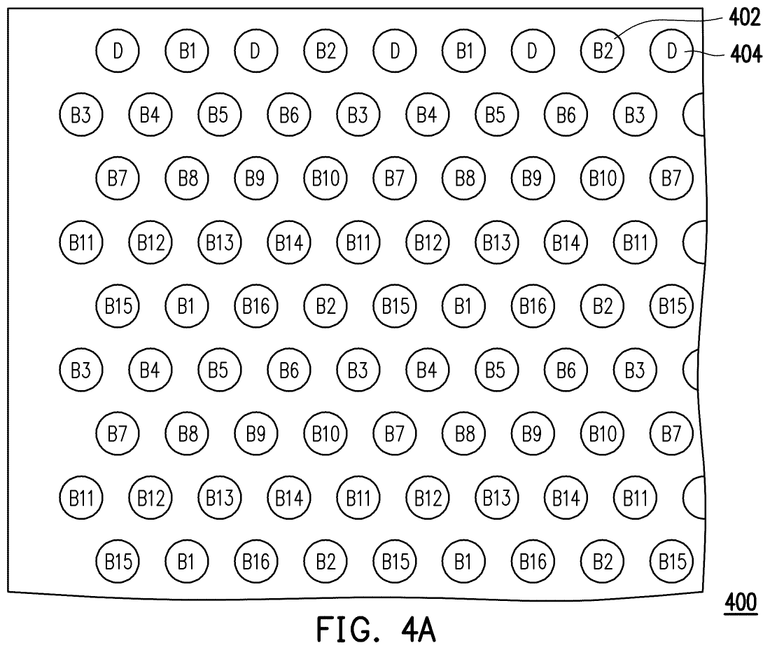

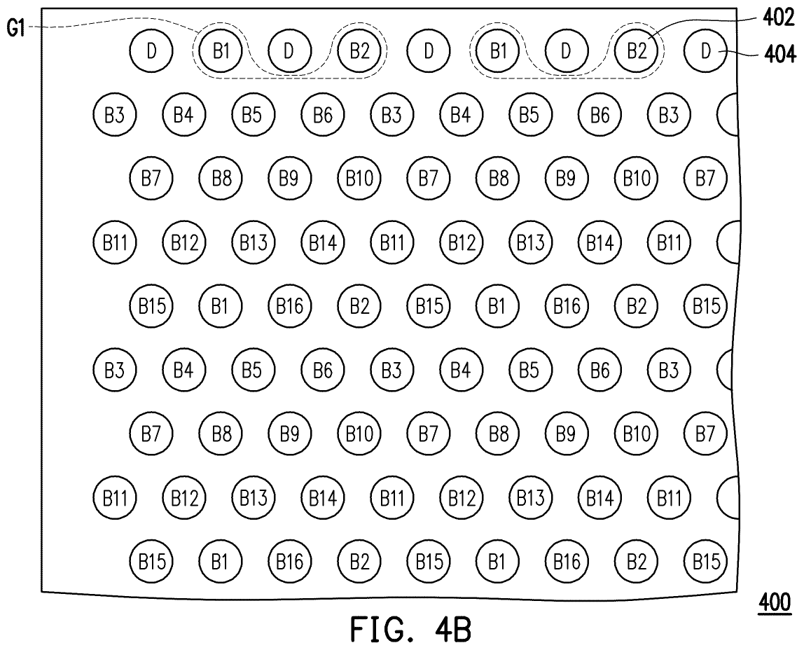

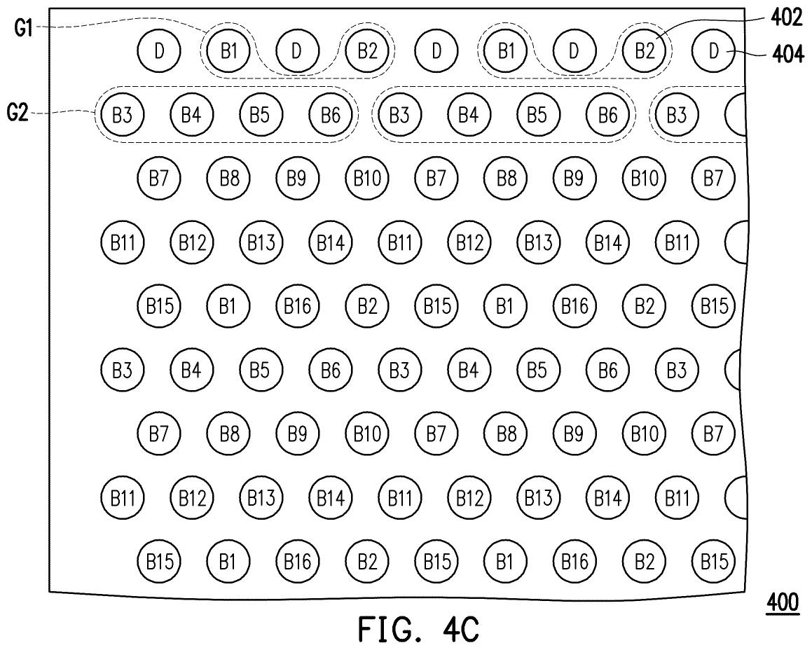

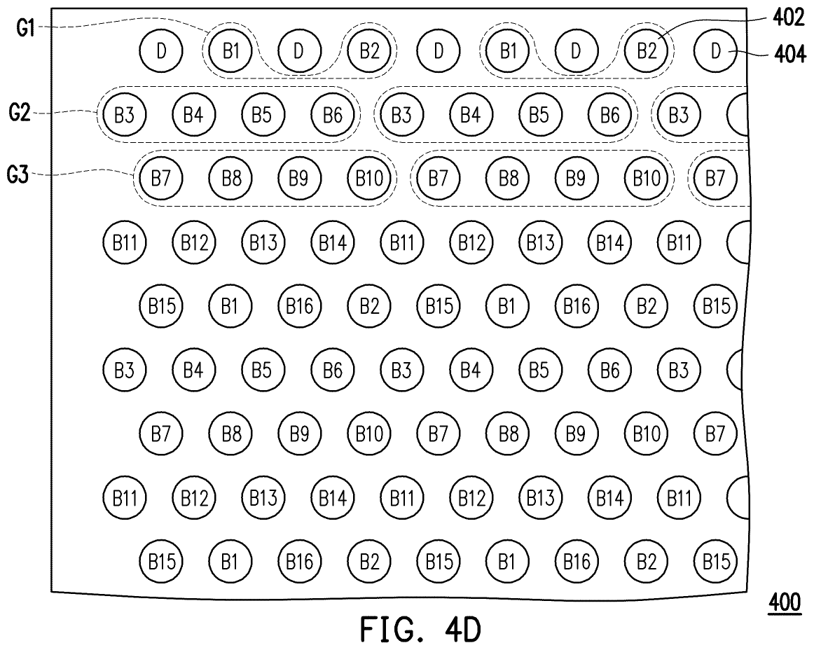

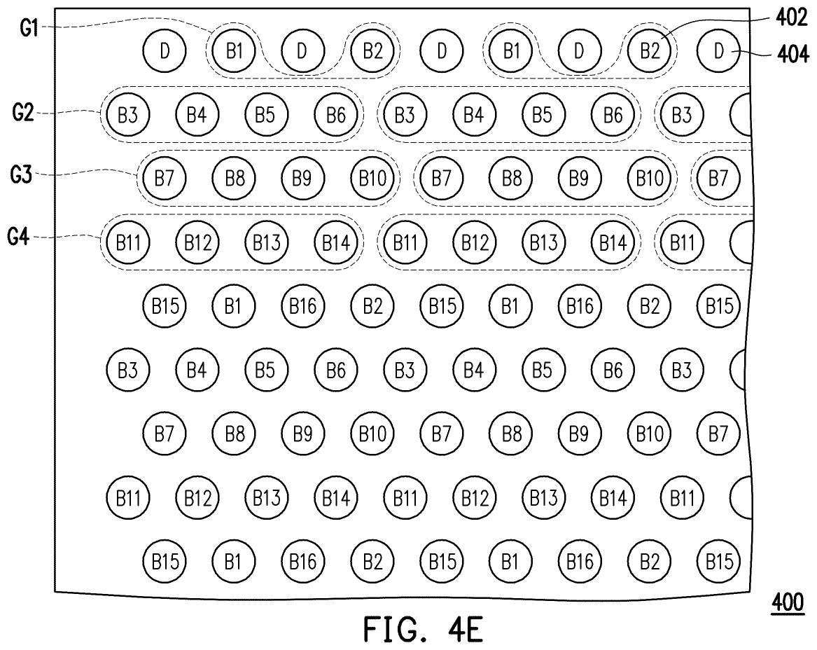

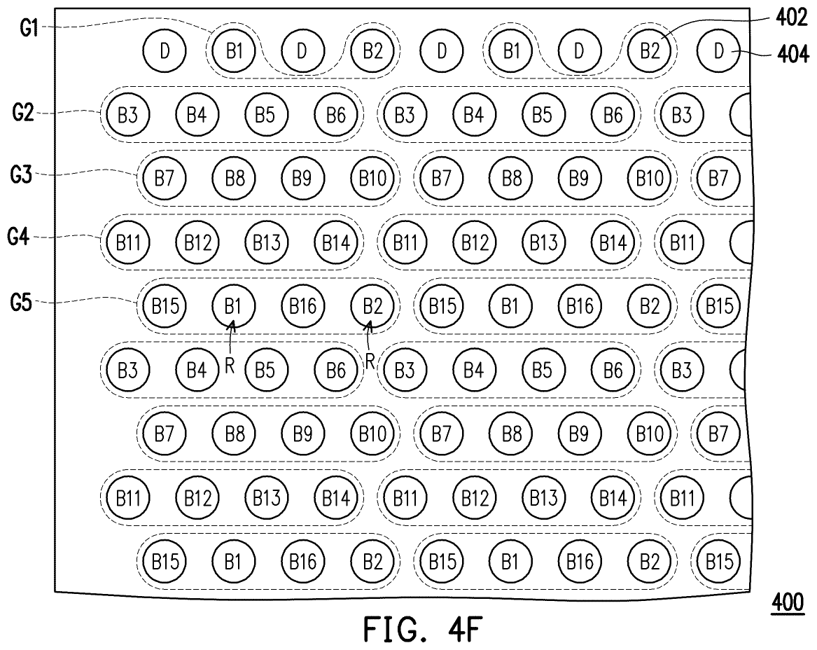

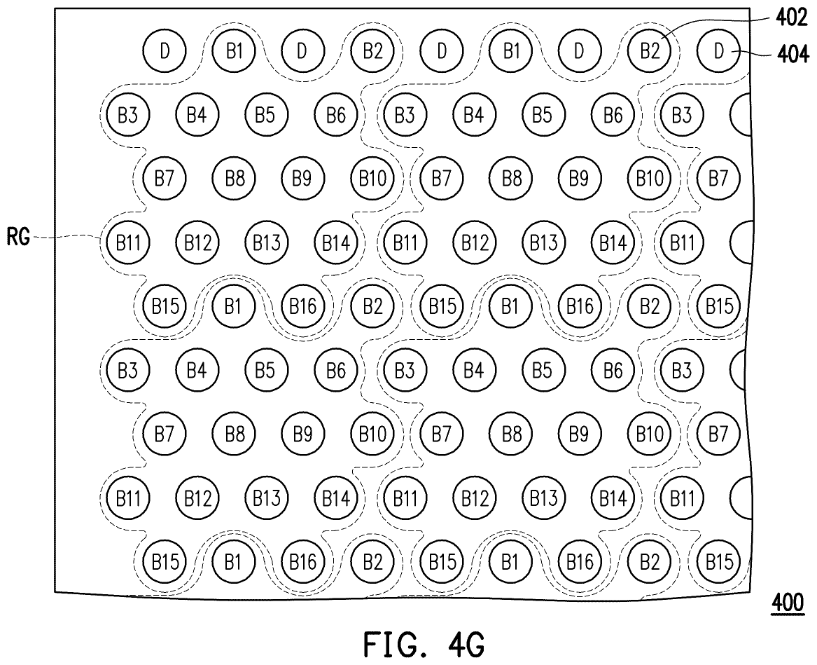

FIG. 3 and FIG. 4A to FIG. 4G illustrate a method for establishing a memory cell group according to a second embodiment of the disclosure.

With reference to FIG. 3 and FIG. 4A, in step 300, a memory cell array 400 including a plurality of memory cells 402 and a plurality of dummy memory cells 404 is provided. In this embodiment, the first row of the memory cell array 400 includes the memory cells 402 and the dummy memory cells 404, while the other rows of the memory cell array 400 do not include the dummy memory cells 404. Except for including the dummy memory cells 404, the structure of the memory cell array 400 is similar to the structure of the memory cell array 200 and thus will not be further elaborated hereinafter. In some embodiments, the dummy memory cells are located in the first row of the memory cell array. In other embodiments, the dummy memory cells are located in a plurality of rows of the memory cell array.

As shown in FIG. 4A, according to the types of the memory cells 402, the memory cells 402 may be respectively marked as B1, B2, B3, . . . , and B16. In addition, the dummy memory cells 404 may be marked as D.

In addition, similar to the first embodiment, in this embodiment, a pattern recognition apparatus that may perform a recognition step on the layout pattern of the memory cell array 400 is provided.

With reference to FIG. 3 and FIG. 4B, the layout pattern of the memory cell array 400 is recognized by the pattern recognition apparatus. In step 302, the memory cells 402 in the first row of the memory cell array 400 are recognized, and the memory cells 402 in the first row are divided into a plurality of row groups G1. In this step, the dummy memory cells 404 are not classified. Therefore, in this embodiment, the memory cells 402 in the first row may be divided into the row groups G1, and the row groups G1 include two different memory cells 402 (marked as B1 and B2 respectively), which should however not be construed as a limitation in the disclosure.

In addition, in this embodiment, since the dummy memory cells 404 are simply disposed at the edge of the memory cell array 400, the dummy memory cells 404 are not included in regions other than the edge of the memory cell array 400.

With reference to FIG. 3 and FIG. 4C, in step 304, the memory cells 402 in the second row of the memory cell array 400 are recognized, and the memory cells 402 in the second row are divided into a plurality of row groups G2. It is then determined whether in the row groups G2 in the second row there are memory cells which are the same as the memory cells in the row groups G1 in the first row. In this embodiment, the row groups G2 include four different memory cells 402 (marked as B3, B4, B5, and B6 respectively), which should however not be construed as a limitation in the disclosure. In this step, it is determined that in the row groups G2 in the second row there are no memory cell which is the same as the memory cells in the row groups G1 in the first row, and thus the recognition step is continuously performed on the next row.

With reference to FIG. 3 and FIG. 4D, in step 306, the memory cells 402 in the third row of the memory cell array 400 are recognized, and the memory cells 402 in the third row are divided into a plurality of row groups G3. It is then determined whether in the row groups G3 in the third row there are memory cells which are the same as the memory cells in the row groups G1 in the first row. In this embodiment, the row groups G3 include four different memory cells 402 (marked as B7, B8, B9, and B10 respectively), which should however not be construed as a limitation in the disclosure. In this step, it is determined that in the row groups G3 in the third row there is no memory cell which is the same as the memory cells in the row groups G1 in the first row, and thus the recognition step is continuously performed on the next row.

With reference to FIG. 3 and FIG. 4E, in step 308, the memory cells 402 in the fourth row of the memory cell array 400 are recognized, and the memory cells 402 in the fourth row are divided into a plurality of row groups G4. It is then determined whether in the row groups G4 in the fourth row there are memory cells which are the same as the memory cells in the row groups G1 in the first row. In this embodiment, the row groups G4 include four different memory cells 402 (marked as B11, B12, B13, and B14 respectively), which should however not be construed as a limitation in the disclosure. In this step, it is determined that in the row groups G4 in the fourth row there is no memory cell which is the same as the memory cells in the row groups G1 in the first row, and thus the recognition step is continuously performed on the next row.

With reference to FIG. 3 and FIG. 4F, in step 310, the memory cells 402 in the fifth row of the memory cell array 400 are recognized, and the memory cells 402 in the fifth row are divided into a plurality of row groups G5. It is then determined whether in the row groups G5 in the fifth row there are memory cells which are the same as the memory cells in the row groups G1 in the first row. In this embodiment, the row groups G5 include four different memory cells 402 (marked as B15, B1, B16, and B2 respectively), which should however not be construed as a limitation in the disclosure.

In this step, it is determined that in the row groups G5 in the fifth row there are memory cells which are the same as the memory cells in the row groups G1 in the first row (the memory cells 402 marked as B1 and B2). At this time, in the row groups G5, the memory cells which are the same as the memory cells in the row groups G1 (the memory cells 402 marked as B1 and B2) are set as repeated memory cells R.

With reference to FIG. 3 and FIG. 4G, in step 312, the memory cells 402 (respectively marked as B15 and B16) other than the repeated memory cells R in the first row group G5 and the memory cells 402 (respectively marked as B1, B2, B3, B4, B5, B6, B7, B8, B9, B10, B11, B12, B13, and B14) in the first row groups (G1, G2, G3, G4) in each of the preceding four rows are collectively established as one memory cell repeating group RG, a total of 16 memory cells 402.

In this embodiment, the memory cell repeating group RG includes 16 different memory cells 402, and the memory cells 402 of 16 types cover all types of memory cells in the memory cell array 400. As such, based on the memory cell repeating group RG, the memory cell array 400 may be considered as being composed of a plurality of the memory cell repeating groups RG. For instance, the repeated memory cells R (respectively marked as B1 and B2) in the first row group G5 in the fifth row, the memory cells 402 (respectively marked as B3, B4, B5, B6, B7, B8, B9, B10, B11, B12, B13, and B14) in the first row groups in the sixth to eighth rows, and the memory cells 402 (marked as B15 and B16) other than the repeated memory cells R in the first row group in the ninth row are established as another identical memory cell repeating group RG.

Besides, in this embodiment, after step 312, step 314 may be further performed to determine whether in the first row group in the fifth row the memory cells 402 constituting the memory cell repeating group RG and the memory cells 402 other than the repeated memory cells R in the first row group G5 from the fifth row to the first row group in the ninth row are repeated. As such, the memory cell array 400 is ensured to be composed of a plurality of the memory cell repeating groups RG.

To sum up, according to the method provided in one or more embodiments of the disclosure, the layout pattern of the memory cell array may be rapidly and accurately recognized and classified by the pattern recognition apparatus, so as to establish the memory cell repeating group, which is conducive to subsequent analyses of product yield and failure modes.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method for establishing a memory cell group comprising different memory cells, the method comprising:
providing a memory cell array comprising a plurality of memory cells and a layout pattern of the memory cell array;
providing a pattern recognition apparatus for performing a recognition step on the layout pattern, wherein the recognition step comprises:
dividing the memory cells in an n^{th} row of rows in the memory cell array into a plurality of row groups, wherein the row groups are identical, and the memory cells in the row groups are different; and
determining whether preceding n rows and succeeding n rows of the rows are repeated; and
according to a recognition result provided by the pattern recognition apparatus through performing the recognition step, collectively establishing a portion of the memory cells as a memory cell repeating group, so that the memory cell array is composed of a plurality of the memory cell repeating groups.

2. The method for establishing the memory cell group according to claim 1, according to a result of performing the recognition step on the n^{th} row:
(a) when the preceding n rows and the succeeding n rows are repeated, collectively establishing the memory cells in a first row group in each row of the preceding n rows as the memory cell repeating group, and
(b) when the preceding n rows and the succeeding n rows are not repeated, performing the recognition step on a next row of the rows until (a) is satisfied.

3. The method for establishing the memory cell group according to claim 2, wherein after providing the pattern recognition apparatus, the recognition step is performed on a first row of the rows in the memory cell array.

4. The method for establishing the memory cell group according to claim 1, wherein the recognition step performed on the layout pattern comprises recognizing a layer stacking structure of each of the memory cells.

5. The method for establishing the memory cell group according to claim 4, wherein the difference in the memory cells comprises a difference in the layer stacking structures of the memory cells.

6. A method for establishing a memory cell group comprising different memory cells, the method comprising:
providing a memory cell array comprising a plurality of memory cells and a plurality of dummy memory cells and a layout pattern of the memory cell array, wherein a first row of rows in the memory cell array comprises the dummy memory cells;
providing a pattern recognition apparatus for performing a recognition step on the layout pattern, wherein the recognition step comprises:
dividing the memory cells in an n^{th} row of the rows in the memory cell array into a plurality of row groups, wherein the row groups are identical, and the memory cells in the row groups are different; and
determining whether in the row groups in the n^{th} row there are memory cells which are identical to the memory cells in the row group in the first row, where n is a positive integer greater than 1; and
according to a recognition result provided by the pattern recognition apparatus through performing the recognition step, collectively establishing a portion of the memory cells as a memory cell repeating group, so that the memory cell array is composed of a plurality of the memory cell repeating groups.

7. The method for establishing the memory cell group according to claim 6, according to a result of performing the recognition step on the n^{th} row:
(a) when in the row groups in the n^{th} row there are memory cells which are identical to the memory cells in the row group in the first row, setting the memory cells in the row groups in the n^{th} row that are identical to the memory cells in the row groups in the first row as repeated memory cells, and collectively establishing the memory cells in the row groups in the n^{th} row other than the repeated memory cells and the memory cells in the first row group in each of preceding (n-1)^{th} rows of the rows as a memory cell repeating group, and
(b) when in the row groups in the n^{th} row there is no memory cell which is identical to the memory cells in the row groups in the first row, performing the recognition step on a next row of the rows until (a) is satisfied.

8. The method for establishing the memory cell group according to claim 7, wherein after providing the pattern recognition apparatus, the recognition step is sequentially performed on the first row and a second row of the rows in the memory cell array.

9. The method for establishing the memory cell group according to claim 8, wherein after establishing the memory cell repeating group, the method further comprises:
determining whether the memory cells in the memory cell repeating group other than the repeated memory cells from the first row group in the n^{th} row to a first row group in a (2n-1)^{th} row of the rows are repeated.

10. The method for establishing the memory cell group according to claim 6, wherein the recognition step performed on the layout pattern comprises recognizing a layer stacking structure of each of the memory cells.

11. The method for establishing the memory cell group according to claim 10, wherein the difference in the memory cells comprises a difference in the layer stacking structures of the memory cells.
